(19) United States
(12) Patent Application Publication
(10) Pub. No.: US 2024/0021239 A1
(43) Pub. Date: Jan. 18, 2024

(54) Hardware Acceleration System for Data Processing, and Chip

(71) Applicant: AMICRO SEMICONDUCTOR CO., LTD., Zhuhai, Guangdong (CN)

(72) Inventors: Zaisheng HE, Zhuhai, Guangdong (CN); Gangjun XIAO, Zhuhai, Guangdong (CN)

(21) Appl. No.: 18/035,504

(22) PCT Filed: Jun. 3, 2021
(86) PCT No.: PCT/CN2021/098175

§ 371 Date: May 4, 2023

(30) Foreign Application Priority Data
Nov. 5, 2020 (CN) 202011221797.X

(51) Int. Cl. G11C 11/413

(52) U.S. Cl. CPC G11C 11/413

(57) ABSTRACT

Disclosed are a hardware acceleration system for data processing, and a chip. The hardware acceleration system is configured to read and write its external Double Date Rate (DDR) storage unit. The hardware acceleration system includes a control unit, a data reading unit, a Static Random Access Memory (SRAM) dedicated storage unit, a register configuration unit, an arithmetic unit and a data write-back unit. Under the monitoring and control of the control unit, for each to-be-processed data block, the data reading unit only uses one read operation to complete the reading of a current to-be-processed data block from the DDR storage unit, and the data write-back unit only uses one write operation to complete the writing-back of all operation results of the current to-be-processed data block to the DDR storage unit.

### CROSS-REFERENCE TO RELATED APPLICATION

This disclosure claims priority to Patent Application No. 202011221797.X filed on Nov. 5, 2020 and entitled “Hardware Acceleration System for Data Processing, and Chip”, the disclosure of which is hereby incorporated by reference in its entirety.

### TECHNICAL FIELD

The present disclosure relates to the technical field of data processing, and in particular to a hardware acceleration system for data processing, and a chip.

### BACKGROUND

At present, as images and videos become larger in pixel size, it is more difficult to process the images and video streams, and requirements for hardware are also increasing. Not only is a processor clock speed required to be high (because too much software is involved, the processor clock speed must be at least 1 GHz), the capacity of memory media (mainly Double Date Rate (DDR) and Static Random Access Memory (SRAM)) also needs to be large, and an access speed is the faster the better. Correspondingly, in order to meet these requirements, the cost of chips is rising, and the requirements on the manufacturing process are getting higher and higher, so that common enterprises cannot make these high-end chips.

For a large amount of data that needs to be processed, the current general method is that CPU software performs frequent data reading from a bulk memory, writes back intermediate results, reads again, operates again, writes back again, and so on iteratively until all processing steps are completed. This method has a high requirement for the bandwidth of a DDR memory due to the frequent access to the DDR. As a result, the total bandwidth demands of the system increase, and the power consumption increases, which affects the system performance. Another method is increasing the capacity of an SRAM built in the CPU to reduce the number of times of reading and writing back to the DDR. Although this method may reduce the number of times of accessing the DDR and the bandwidth demand for the DDR to a certain extent, the result is that the area of the SRAM increases and the cost rises.

### SUMMARY

The present disclosure proposes a hardware acceleration system for data processing, and a chip. Specific technical solutions are as follows.

A hardware acceleration system for data processing is provided. The hardware acceleration system is configured to read and write its external DDR storage unit. The hardware acceleration system include: a control unit, a data reading unit, an SRAM dedicated storage unit, a register configuration unit and an arithmetic unit, the control unit is electrically connected to the register configuration unit, the data reading unit is electrically connected to the control unit, the data reading unit is electrically connected to the DDR storage unit, and the data reading unit is configured to read a current to-be-processed data block from the DDR storage unit through one read operation by block transmission information currently saved in the register configuration unit under the reading control of the control unit, the SRAM dedicated storage unit is electrically connected to the data reading unit, and the data reading unit is configured to write the current to-be-processed data block into the SRAM dedicated storage unit; the SRAM dedicated storage unit is electrically connected to the arithmetic unit, the arithmetic unit is electrically connected to the control unit, and the control unit is configured to start the arithmetic unit to perform an operation processing on the current to-be-processed data block written into the SRAM dedicated storage unit according to a preset logical operation structure after monitoring that the data reading unit completes the read operation on the current to-be-processed data block, so that bandwidths of the SRAM dedicated storage unit are all occupied by the arithmetic unit; the control unit is further configured to refresh the block transmission information currently saved in the register configuration unit after the arithmetic unit completes the operation processing on the current to-be-processed data block, so as to the block transmission information currently saved with a block transmission information stored in the DDR storage unit based on a next to-be-processed data block; the block transmission information includes: a start address of the current to-be-processed data block, a byte size of the current to-be-processed data block, a write-back address of an operation result obtained from the operation processing performed on the current to-be-processed data block by the arithmetic unit, and a byte size of the operation result obtained from the operation processing performed on the current to-be-processed data block by the arithmetic unit. Both the start address and the write-back address are data storage addresses of the DDR storage unit.

Further, the hardware acceleration system also include a data write-back unit, configured to write, after the control unit monitors that the arithmetic unit outputs a last operation result based on the current to-be-processed data block, these operation results into the DDR storage unit in a write-once mode or a burst write mode according to the block transmission information currently saved, so that the data write-back unit by only one write operation to complete the writing-back of all of the operation results of the current to-be-processed data block to the DDR storage unit.

Further, the control unit is further configured to send an interrupt instruction to inform a CPU after the arithmetic unit completes the operation processing of all of to-be-processed data blocks in the DDR storage unit, so that the CPU starts to process the operation results which have been written into the DDR storage unit.

Further, the CPU is configured to write, before the data reading unit reads a first to-be-processed data block from the DDR storage unit, the block transmission information into the register configuration unit; so that the data reading unit reads one to-be-processed data block from the DDR storage unit each time; the control unit is configured to start, after the CPU writes the block transmission information into the register configuration unit, the data reading unit to read the first to-be-processed data block from the DDR storage unit.

Further, under the reading control of the control unit, the to-be-processed data block read by the data reading unit from the DDR storage unit is: one or more to-be-processed data blocks obtained by dividing all to-be-processed data stored inside the DDR storage unit according to data amount of the block transmission information that supports real-time refresh.

Further, based on the block transmission information saved in the register configuration unit, data amount of the to-be-processed data block read by the data reading unit each time is different.

Further, data amount of the to-be-processed data block is set according to a frame rate of images input from outside to the DDR storage unit, so as to support the hardware acceleration system to timely process image data stored in the DDR storage unit in blocks; or, the data amount of the to-be-processed data block is set according to a frame rate of laser data input from the outside to the DDR storage unit, so as to support the hardware acceleration system to timely process laser point cloud maps stored in the DDR storage unit in blocks.

Further, space capacity of the SRAM dedicated storage unit is configured as a sum of data amount in the to-be-processed data block read by the data reading unit each time and data amount of intermediate data preexisting in the data reading unit.

A chip is provided. The chip includes the hardware acceleration system in the above technical solution.

### BRIEF DESCRIPTION OF THE DRAWINGS

FIG. 1 is a frame diagram of a hardware acceleration system for data processing claimed in the present disclosure.

### DETAILED DESCRIPTION OF THE EMBODIMENTS

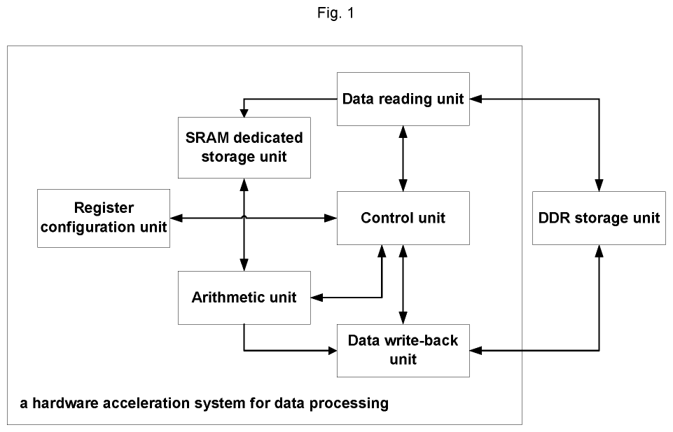

Specific implementation modes of the present disclosure are further described below in combination with the accompanying drawings. Modules involved in the following implementation modes are logical circuit units. A logical circuit unit may be a physical unit, or a state machine composed of multiple logical devices according to a certain reading and writing timing sequence and logical signal change, or a part of a physical unit, or realized by a combination of multiple physical units. Moreover, in order to highlight the innovative part of the present disclosure, the implementation modes of the present disclosure do not introduce units which have little to do with solving the technical problem presented in the present disclosure, but it doesn't mean there is no other unit in the implementation modes of the present disclosure. It is to be noted that the DDR described in the present disclosure refers to the DDR storage unit shown in FIG. 1, and the SRAM described in the present disclosure refers to the SRAM dedicated storage unit shown in FIG. 1.

The present disclosure proposes new data processing architecture based on the existing common technological process. In the case that requirements on a processor clock speed are not high, the new data processing architecture can achieve cyclic data processing like hardware automatic reading, computation, writing back, setting flag bit, automatic reading, computation, writing back, and setting flag bit for processing big data, which reduces software intervention, reduces the number of times of accessing DDR, reduces the bandwidth demand for the DDR, reduces the hardware scale, and thus reduces the cost of chips.

As shown in FIG. 1, an embodiment of the present disclosure discloses a hardware acceleration system for data processing. The hardware acceleration system is configured to read and write its external DDR storage unit. The hardware acceleration system includes a control unit, a data reading unit, an SRAM dedicated storage unit, a register configuration unit and an arithmetic unit. There is an electrical connection relation between the control unit and the register configuration unit. There is a signal receiving and sending relation between a data command port of the control unit and a data command port corresponding to the register configuration unit. The control unit may automatically refresh the register configuration unit.

There is an electrical connection relation between the data reading unit and the control unit, and this electrical connection relation is a connection relation among ports with a signal receiving and sending response relation, including a command port. There is an electrical connection relation between the data reading unit and the DDR storage unit, and this electrical connection relation is a connection relation among ports with data receiving and sending response relation, including at least one address port and at least one data port. The data reading unit is configured to read a current to-be-processed data block from the DDR storage unit through one read operation by block transmission information currently saved in the register configuration unit under reading control of the control unit, and cache the current to-be-processed data block into a First In First Out (FIFO) memory set in the data reading unit, and the reading control is a control command transmitted by the control unit, specifically the read control command, which is used to control the data reading unit to use the block transmission information saved by the register configuration unit to read a to-be-processed data block from the DDR storage unit through the read operation, thereby reducing CPU intervention. The block transmission information includes: a start address of the current to-be-processed data block, a byte size of the current to-be-processed data block, a write-back address of an operation result obtained from the operation processing performed on the current to-be-processed data block by the arithmetic unit, and a byte size of the operation result obtained from the operation processing performed on the current to-be-processed data block by the arithmetic unit; both the start address and the write-back address are data storage addresses of the DDR storage unit These block transmission information represents byte memory operation information that is configured to the control unit and the data reading unit and can be executed by a hardware circuit.

In some embodiments, the CPU is configured to write, before the data reading unit reads a first to-be-processed data block from the DDR storage unit, the block transmission information into the register configuration unit, so that the data reading unit can read only one to-be-processed data block from the DDR storage unit at a time, instead of reading the data one by one. It is to be noted that such a method of dividing a large amount of data into small data blocks and then performing linked transmission is referred to as a linked list transmission mode.

There is an electrical connection relation between the SRAM dedicated storage unit as a memory and the data reading unit, and this electrical connection relation is a connection relation among ports with the data receiving and sending response relation, including at least one address port, at least one data port and at least one command port. The data reading unit is configured to write the current to-be-processed data block into the SRAM dedicated storage unit, and the SRAM dedicated storage unit is configured to automatically read and receive the to-be-processed data block read by the data reading unit. The space capacity of the SRAM dedicated storage unit is configured as a sum of data amount in the to-be-processed data block read by the data reading unit each time and data amount of intermediate data preexisting in the data reading unit, and the space capacity refers to storage capacity; the intermediate data is data left in the data reading unit before reading the current to-be-processed data block, and the intermediate data includes some unprocessed data in the previous to-be-processed data block and other types of data which are buffered to the data reading unit in advance. Redundant memory space is reserved for the SRAM dedicated storage unit to ensure that the data reading unit can receive all the data blocks needing to be processed under a current read operation, so that the arithmetic unit monopolizes the bandwidth of the data reading unit when performing a computing operation. The data amount in the to-be-processed data block read each time is taken as a dividing unit of all the to-be-processed data stored inside the DDR storage unit, and the data amount in the to-be-processed data block read each time is taken as a byte size of the to-be-processed data block, which is memory information that can be recognized by hardware circuits.

There is an electrical connection relation between the SRAM dedicated storage unit and the arithmetic unit, and this electrical connection relation is a connection relation among ports with the data receiving and sending response relation, including at least one address port, at least one data port and at least one command port. There is an electrical connection relation between the arithmetic unit and the control unit, and this electrical connection relation is a connection relation among ports with the signal receiving and sending response relation, including at least one command port. The control unit is configured to start the arithmetic unit to perform an operation processing on the current to-be-processed data block according to a preset logical operation structure after monitoring that the data reading unit completes the read operation on the current to-be-processed data block, so that bandwidths of the SRAM dedicated storage unit are all occupied by the arithmetic unit. After the data reading unit writes the current to-be-processed data block into the SRAM dedicated storage unit, the arithmetic unit can monopolize the SRAM dedicated storage unit when using the to-be-processed data of the SRAM dedicated storage unit for operation, thereby realizing that all the bandwidths of the SRAM dedicated storage unit are occupied by the arithmetic unit. In this way, although the data blocks of the SRAM dedicated storage unit are accessed frequently, the impact on the occupancy of the bandwidth of the DDR is minimized.

After the arithmetic unit completes all the operation processing on the current to-be-processed data block, the control unit refreshes the block transmission information currently saved in the register configuration unit, and replaces the block transmission information stored in the DDR storage unit based on a next to-be-processed data block with the block transmission information currently saved; after the register configuration unit is refreshed, the saved block transmission information includes the byte size of the next to-be-processed data block; then, under the reading control of the control unit, the data reading unit uses the block transmission information currently saved in the register configuration unit, namely the block transmission information stored by the register configuration unit based on the next to-be-processed data block, to perform a read operation to complete the reading of the next to-be-processed data block from the DDR storage unit, and then writes the next to-be-processed data block into the SRAM dedicated storage unit; then, under the monitoring and control of the control unit, the data reading unit is configured to start, after completing the read operation on the next to-be-processed data block, the arithmetic unit to perform the operation processing on the next to-be-processed data block according to a preset logical operation structure, so that the bandwidths of the SRAM dedicated storage unit is kept occupied by the arithmetic unit once again. Therefore, in a process of reading and processing the to-be-processed data block inside the DDR storage unit in blocks, the hardware acceleration system for data processing calls, through the control unit, each module unit to repeat the above transmission operation process, to achieve a large number of data block transmission and operation processing, and form hardware iterative processing of a large number of data digital circuit state machine mechanism.

Compared with the related art, in this embodiment, under the monitoring and control of the control unit, for each to-be-processed data block, the data reading unit uses only one read operation to read the current to-be-processed data block from the DDR storage unit, while the SRAM dedicated storage unit needs to accept multiple read and write accesses from an external unit to ensure that the arithmetic unit can complete the operation processing on the current to-be-processed data block without relying on the CPU. In this way, previous operations needing to frequently access a large amount of data of the DDR are changed to frequently accessing data blocks in the dedicated SRAM, there is no need to increase the capacity of the SRAM, and unnecessary CPU intervention is reduced; at the same time, the number of times of accessing the DDR is also reduced, and the requirement of the hardware acceleration system for the bandwidth of the DDR is reduced.

In the above embodiment, the hardware acceleration system also includes a data write-back unit. When the arithmetic unit performs operation processing on a piece of data in a to-be-processed data block transmitted by the SRAM dedicated storage unit and outputs an operation result, the operation result continues to be transmitted to the data write-back unit, and the data write-back unit is also provided with an FIFO cache for caching the operation result. After the control unit monitors that the arithmetic unit outputs a last operation result based on the current to-be-processed data block, the data write-back unit is configured to write these operation results into the DDR storage unit in a write-once mode or a burst write mode according to the block transmission information currently saved. Specifically, when the number of operation results output by the arithmetic unit is relatively large, that is, the byte size, for example, 6 bytes or more than 6 bytes, of the operation results output by the arithmetic unit reaches a burst transmission length configured by the control unit, under the control of AHB bus protocol command parameters configured by the control unit, these operation results are written back to the DDR storage unit in a burst write mode (burst transmission mode). Specifically, when the byte size of the operation results output by the arithmetic unit is relatively small, for example 2 bytes, and reaches a single transmission length configured by the control unit, under the control of the AHB bus protocol command parameters configured by the control unit, these operation results are written back to the DDR storage unit in a write-once mode (single transmission mode). Thus, the data write-back unit completes the writing-back of all the operation results of the current to-be-processed data block back to the DDR storage unit through one write operation. Therefore, in this embodiment, the data write-back unit uses only one write operation to complete the writing-back of all operation results of the current to-be-processed data block to the DDR storage unit, so that for one to-be-processed data block, the access to the DDR by the hardware acceleration system only includes one read operation and one write operation, which saves the bandwidth of the DDR and improves a data processing speed.

Preferably, in this embodiment, taking the minimum amount of data (byte size) as a unit, a large amount of data stored in the DDR storage unit is divided, and the start address, byte size, write-back address after the operation processing and other information of each divided to-be-processed data block are stored as the block transmission information that can be called by the control unit. Before a first to-be-processed data block is read from the DDR storage unit, the CPU writes the block transmission information required for the first transmission into the register configuration unit as the block transmission information needed by the data reading unit to read the to-be-processed data block for the first time, and then starts transmission. After the CPU writes the block transmission information into the register configuration unit, the control unit starts the data reading unit to read the first to-be-processed data block from the DDR storage unit. The block transmission information includes: the start address of the current to-be-processed data block, the byte size of the current to-be-processed data block, the write-back address of the operation result obtained from the operation processing performed on the current to-be-processed data block by the arithmetic unit, and the byte size of the operation result obtained from the operation processing performed on the current to-be-processed data block by the arithmetic unit. For example, the data reading unit will transmit 1KB data; if the 1KB data is 32-bit, the byte size of the 1KB data is 256 (storage value range), namely 1-byte length. Therefore, the block transmission information currently configured in the register configuration unit is used for indicating that the hardware acceleration system currently reads and writes address information of the external DDR storage unit, so as to ensure that the hardware acceleration system can normally perform the operation of reading the current to-be-processed data block at a time, and ensure that the hardware acceleration system can normally perform the operation of writing the operation result in the burst write mode. After the arithmetic unit completes all operation processing of the current to-be-processed data block, the control unit, instead of the CPU, automatically refreshes the block transmission information currently saved in the register configuration unit, so as to replace the block transmission information stored in the DDR storage unit based on the next to-be-processed data block with the currently saved block transmission information. After the register configuration unit is refreshed, the saved block transmission information includes: the byte size of the next to-be-processed data block, the start address of the next to-be-processed data block, the write-back address of the operation result obtained from the operation processing performed on the next to-be-processed data block by the arithmetic unit, and the byte size of the operation result obtained from the operation processing performed on the next to-be-processed data block by the arithmetic unit. Therefore, the refreshed block transmission information in the register configuration unit is used for indicating that the hardware acceleration system reads and writes address information of the external DDR storage unit next time, so as to ensure that the hardware acceleration system can normally perform the operation of reading the next to-be-processed data block at a time, and ensure that the hardware acceleration system can normally perform the operation of writing the operation result in the burst write mode next time.

In this embodiment, the control unit is further configured to send an interrupt instruction to inform the CPU after the arithmetic unit completes the operation processing of all of to-be-processed data blocks in the DDR storage unit, so that the CPU starts to process the operation results which have been written into the DDR storage unit, that is to say, the interrupt instruction is an instruction to instruct the CPU to process the operation results which have been written into the DDR storage unit. This embodiment may use an interrupt condition to inform the CPU to refresh the register configuration unit or the DDR storage unit, may support the processing of unlimited amount of data (byte size), and is applicable to a large amount of continuous multi-frame image data or laser point cloud data acquired in real time. Thus, the whole process no longer involves the CPU except configuring the register configuration unit by the CPU when the to-be-processed data block is read from the DDR storage unit at the very beginning and sending an interrupt to the CPU when all operations are finished and the operation results are output to the data write-back unit, and the occupancy of CPU resource is almost negligible.

In this embodiment, the control unit plays the role of a co-processor; as a host module, the control unit completes timely reading, computing and writing-back operations according to monitoring states of the data reading unit, the register configuration unit, the arithmetic unit and the data write-back unit; the response speed is fast, CPU intervention is not required, and the access to the DDR is reduced. On this basis, in this embodiment, the data reading unit is controlled to read one to-be-processed data block from the DDR storage unit each time based on the block transmission information currently saved in the register configuration unit. Both the start address and the write-back address are data storage addresses of the DDR storage unit. The block transmission information indicates that the hardware acceleration system reads and writes the address information and the byte size information of the external DDR storage unit, so as to ensure that the hardware acceleration system can orderly perform the operation of reading each to-be-processed data block at a time, and ensure that a burst write operation of the operation results in the hardware acceleration system is performed orderly.

In some embodiments, under the reading control of the control unit, the to-be-processed data block read by the data reading unit from the DDR storage unit is: one or more to-be-processed data blocks obtained by dividing all to-be-processed data stored inside the DDR storage unit according to the byte size of the block transmission information that supports real-time refresh. In this embodiment, after a large amount of to-be-processed data is divided into one or more to-be-processed data blocks, under the reading control of the control unit, different to-be-processed data blocks of the DDR storage unit need to be read sequentially according to the block transmission information refreshed in real time, which increases the number of times of accessing the SRAM dedicated storage unit and reduces the byte size shared by each cache of the SRAM dedicated storage unit. Preferably, based on the block transmission information saved in the register configuration unit, the byte size and address of the to-be-processed data block read by the data reading unit each time are different. Thus, the byte size and address information of the data blocks transmitted in blocks is configured flexibly to meet requirements for the data processing speeds in various scenarios.

As an embodiment, according to the block transmission information currently saved in the register configuration unit, one to-be-processed data block with a byte size of 6 bytes is segmented from the to-be-processed data inside the DDR storage unit, and is read by the data reading unit at a time, that is, data is transmitted from the DDR storage unit to the data reading unit in blocks, and then operated in the hardware acceleration system in the way of the foregoing embodiment. After the operation result of the to-be-processed data block with the byte size of 6 bytes is output or it is considered that the operation processing of the to-be-processed data block with the byte size of 6 bytes is finished, the block transmission information currently saved in the register configuration unit is refreshed by the control unit to the block transmission information based on the next to-be-processed data block, and then according to the new block transmission information obtained after refreshing the register configuration unit, one to-be-processed data block with the byte size of 8 bytes is segmented from the to-be-processed data inside the DDR storage unit, and is read by the data reading unit at a time, that is, data is transmitted from the DDR storage unit to the data reading unit in blocks, and then operated in the hardware acceleration system in the way of the foregoing embodiment. That is, iterative processing is performed until all of the to-be-processed data stored inside the DDR storage unit are transmitted into the hardware acceleration system in blocks. In this way, the increase of the capacity of the SRAM in the process of reading and writing the SRAM is avoided, and the occupied area of the SRAM is reduced.

In some embodiments, data amount of the to-be-processed data block is set according to a frame rate of images input from outside to the DDR storage unit, so as to support the hardware acceleration system to timely process image data stored in the DDR storage unit in blocks under the premise of less CPU intervention, and save bandwidth resources of the DDR storage unit. This is especially suitable for occasions of accelerated processing of multi-frame images. Or, the data amount of the to-be-processed data block is set according to a frame rate of laser data input from the outside to the DDR storage unit, so as to support the hardware acceleration system to timely process laser point cloud maps stored in the DDR storage unit in blocks, and the laser data is point cloud data in the laser point cloud map. This is suitable for occasions of accelerated processing of multi-frame images or segmenting laser point cloud maps. The data amount of the to-be-processed data block is equal to the byte size of the to-be-processed data block.

In some embodiments, space capacity of the SRAM dedicated storage unit is configured as a sum of data amount in the to-be-processed data block read by the data reading unit each time and data amount of intermediate data preexisting in the data reading unit. There is some intermediate data co-existing with the to-be-processed data block that has been read into the data reading unit, and these intermediate data also needs to be written into the SRAM dedicated storage unit. This embodiment reserves redundant memory space for the SRAM dedicated storage unit to ensure that the data reading unit can receive all the data blocks needing to be processed under each read operation (reading one to-be-processed data block from the DDR storage unit each time), so that the arithmetic unit monopolizes the bandwidth of the data reading unit when performing a computing operation. The data amount of the to-be-processed data block is equal to the byte size of the to-be-processed data block.

A chip is provided. The chip includes the hardware acceleration system in the above technical solution. The chip automatically divides a large amount of data according to an actual hardware situation (including the memory capacity of a DDR memory and an on-chip SRAM storage unit), which reduces the requirement for the bandwidth of peripheral memories, reduces the number of times of accessing the DDR, and reduces the requirement for the bandwidth of the DDR without increasing the capacity of the on-chip SRAM; at the same time, the reading of data blocks, the processing of data blocks, and the writing-back of operation results are completed relying on a data processing architecture inside the chip. Almost the whole process involves only hardware, so the software intervention is reduced. Especially when massive data is processed, as long as CPU software presets the register configuration unit or refreshes the register configuration unit according to an interrupt condition, data amount that can be processed in blocks is unlimited, which is not restricted by the number of image frames or the amount of laser point cloud data acquired in real time.

It is to be noted that the data reading unit, the control unit, the arithmetic unit and the data write-back unit are all state machines realized by hardware languages. The control unit is used as a master state machine, and the others are used as slave state machines. The master state machine is composed of a state register and a combinational logic circuit, and is configured to schedule the automatic operation of the slave state machine in batches according to the block transmission information configured in the register configuration unit, so as to realize the iterative processing of reading and writing the to-be-processed data, so that functional unit modules involved in the embodiments of the present disclosure are all composed of digital arithmetic circuits.

It is to be noted that the insides of both the DDR storage unit and the SRAM dedicated storage unit are storage arrays, the DDR storage unit is understood as the DDR in the above background technology, the bandwidth of the DDR is the bandwidth of the DDR storage unit, and the SRAM dedicated storage unit is understood as the SRAM in the above background technology. To “fill” the to-be-processed data in, as a retrieval principle of tables, first a row is specified, then a column is specified, and a necessary cell is found accurately. This is the basic principle of addressing of a memory chip. For the memory, this cell may be called a storage unit, and then this table (storage array) is a logical bank (bank for short). In a process of block transmission (a method of dividing a large amount of data into small data blocks and then performing the linked transmission in the foregoing embodiments) of the data reading unit and the DDR storage unit, the start addresses of sending each to-be-processed data block are not necessarily aligned, but a division of storage space (logical bank) is also realized. With this division as the premise, the start address of sending the to-be-processed data block is determined by the width (data amount) of the to-be-processed data block in each block transmission. In a burst transmission process of the data write-back unit and the DDR storage unit, the start addresses of each burst transmission are aligned, and a division of storage space (logical bank) can be realized; when an external access is reading or writing data in a burst mode, this division is taken as a premise, and the aligned address is determined by the width of data in each transmission.

In the embodiments provided by the present application, it is to be understood that the disclosed system and chip may be implemented in another manner. For example, the system embodiment described above is only schematic, and for example, division of the units is only logic function division, and other division manners may be adopted during practical implementation. For example, multiple units or components may be combined or integrated into another system, or some characteristics may be neglected or not executed. In addition, coupling or direct coupling or communication connection between each displayed or discussed component may be indirect coupling or communication connection, implemented through some interfaces, of the device or the units, and may be electrical and mechanical or adopt other forms. The units described as separate parts may or may not be physically separated, and parts displayed as units may or may not be physical units, and namely may be located in the same place, or may also be distributed to multiple network units. Part or all of the units may be selected to achieve the purpose of the solutions of the embodiments according to a practical requirement.

What is claimed is:

1. A hardware acceleration system for data processing, configured to read and write its external Double Date Rate (DDR) storage unit, comprising: a control unit, a data reading unit, a Static Random Access Memory (SRAM) dedicated storage unit, a register configuration unit and an arithmetic unit; wherein
the control unit is electrically connected to the register configuration unit, the data reading unit is electrically connected to the control unit, the data reading unit is electrically connected to the DDR storage unit, and the data reading unit is configured to read a current to-be-processed data block from the DDR storage unit through one read operation by block transmission information currently saved in the register configuration unit under reading control of the control unit; the SRAM dedicated storage unit is electrically connected to the data reading unit, and the data reading unit is configured to write the current to-be-processed data block into the SRAM dedicated storage unit;
the SRAM dedicated storage unit is electrically connected to the arithmetic unit, the arithmetic unit is electrically connected to the control unit, and the control unit is configured to start the arithmetic unit to perform an operation processing on the current to-be-processed data block written into the SRAM dedicated storage unit according to a preset logical operation structure after monitoring that the data reading unit completes the read operation on the current to-be-processed data block, so that bandwidths of the SRAM dedicated storage unit are all occupied by the arithmetic unit;
the control unit is further configured to refresh the block transmission information currently saved in the register configuration unit after the arithmetic unit completes the operation processing on the current to-be-processed data block, so as to replace the block transmission information currently saved with a block transmission information stored in the DDR storage unit based on a next to-be-processed data block;
the block transmission information comprises: a start address of the current to-be-processed data block, byte size of the current to-be-processed data block, a write-back address of an operation result obtained from the operation processing performed on the current to-be-processed data block by the arithmetic unit, and byte size of the operation result obtained from the operation processing performed on the current to-be-processed data block by the arithmetic unit; both the start address and the write-back address are data storage addresses of the DDR storage unit.

2. The hardware acceleration system according to claim 1, further comprising:
a data write-back unit, configured to write, after the control unit monitors that the arithmetic unit outputs a last operation result based on the current to-be-processed data block, these operation results into the DDR storage unit in a write-once mode or a burst write mode according to the block transmission information currently saved, so that the data write-back unit by only one write operation to complete the writing-back of all of the operation results of the current to-be-processed data block to the DDR storage unit.

3. The hardware acceleration system according to claim 2, wherein the control unit is further configured to send an interrupt instruction to inform a CPU after the arithmetic unit completes the operation processing of all of to-be-processed data blocks in the DDR storage unit, so that the CPU starts to process the operation results which have been written into the DDR storage unit.

4. The hardware acceleration system according to claim 3, wherein the CPU is configured to write, before the data reading unit reads a first to-be-processed data block from the DDR storage unit, the block transmission information into the register configuration unit;
the control unit is configured to start, after the CPU writes the block transmission information into the register configuration unit, the data reading unit to read the first to-be-processed data block from the DDR storage unit.

5. The hardware acceleration system according to claim 4, wherein under the reading control of the control unit, the to-be-processed data block read by the data reading unit from the DDR storage unit is: one or more to-be-processed data blocks obtained by dividing all to-be-processed data stored inside the DDR storage unit according to data amount of the block transmission information that supports real-time refresh.

6. The hardware acceleration system according to claim 1, wherein based on the block transmission information saved in the register configuration unit, data amount of the current to-be-processed data block read by the data reading unit each time is different, wherein the data amount of the current to-be-processed data block is equal to the byte size of the current to-be-processed data block.

7. The hardware acceleration system according to claim 6, wherein the data amount of the to-be-processed data block is set according to a frame rate of images input from outside to the DDR storage unit, so as to support the hardware acceleration system to timely process image data stored in the DDR storage unit in blocks; or, the data amount of the to-be-processed data block is set according to a frame rate of laser data input from the outside to the DDR storage unit, so as to support the hardware acceleration system to timely process laser point cloud maps stored in the DDR storage unit in blocks.

8. The hardware acceleration system according to claim 7, wherein space capacity of the SRAM dedicated storage unit is configured as a sum of data amount in the to-be-processed data block read by the data reading unit each time and data amount of intermediate data preexisting in the data reading unit.

9. A chip, comprising a hardware acceleration system for data processing, configured to read and write its external Double Date Rate (DDR) storage unit, comprising: a control unit, a data reading unit, a Static Random Access Memory (SRAM) dedicated storage unit, a register configuration unit and an arithmetic unit; wherein
the control unit is electrically connected to the register configuration unit, the data reading unit is electrically connected to the control unit, the data reading unit is electrically connected to the DDR storage unit, and the data reading unit is configured to read a current to-be-processed data block from the DDR storage unit through one read operation by block transmission information currently saved in the register configuration unit under reading control of the control unit; the SRAM dedicated storage unit is electrically connected to the data reading unit, and the data reading unit is configured to write the current to-be-processed data block into the SRAM dedicated storage unit;
the SRAM dedicated storage unit is electrically connected to the arithmetic unit, the arithmetic unit is electrically connected to the control unit, and the control unit is configured to start the arithmetic unit to perform an operation processing on the current to-be-processed data block written into the SRAM dedicated storage unit according to a preset logical operation structure after monitoring that the data reading unit completes the read operation on the current to-be-processed data block, so that bandwidths of the SRAM dedicated storage unit are all occupied by the arithmetic unit;
the control unit is further configured to refresh the block transmission information currently saved in the register configuration unit after the arithmetic unit completes the operation processing on the current to-be-processed data block, so as to replace the block transmission information currently saved with a block transmission information stored in the DDR storage unit based on a next to-be-processed data block;
the block transmission information comprises: a start address of the current to-be-processed data block, a byte size of the current to-be-processed data block, a write-back address of an operation result obtained from the operation processing performed on the current to-be-processed data block by the arithmetic unit, and a byte size of the operation result obtained from the operation processing performed on the current to-be-processed data block by the arithmetic unit; both the start address and the write-back address are data storage addresses of the DDR storage unit.

10. The chip according to claim 9, the hardware acceleration system further comprising:
a data write-back unit, configured to write, after the control unit monitors that the arithmetic unit outputs a last operation result based on the current to-be-processed data block, these operation results into the DDR storage unit in a write-once mode or a burst write mode according to the block transmission information currently saved, so that the data write-back unit by only one write operation to complete the writing-back of all of the operation results of the current to-be-processed data block to the DDR storage unit.

11. The chip according to claim 10, wherein the control unit is further configured to send an interrupt instruction to inform a CPU after the arithmetic unit completes the operation processing of all of to-be-processed data blocks in the DDR storage unit, so that the CPU starts to process the operation results which have been written into the DDR storage unit.

12. The chip according to claim 11, wherein the CPU is configured to write, before the data reading unit reads a first to-be-processed data block from the DDR storage unit, the block transmission information into the register configuration unit;
the control unit is configured to start, after the CPU writes the block transmission information into the register configuration unit, the data reading unit to read the first to-be-processed data block from the DDR storage unit.

13. The chip according to claim 12, wherein under the reading control of the control unit, the to-be-processed data block read by the data reading unit from the DDR storage unit is: one or more to-be-processed data blocks obtained by dividing all to-be-processed data stored inside the DDR storage unit according to data amount of the block transmission information that supports real-time refresh.

14. The chip according to claim 9, wherein based on the block transmission information saved in the register configuration unit, data amount of the to-be-processed data block read by the data reading unit each time is different, wherein the data amount of the to-be-processed data block is equal to the byte size of the to-be-processed data block.

15. The chip according to claim 14, wherein the data amount of the to-be-processed data block is set according to a frame rate of images input from outside to the DDR storage unit, so as to support the hardware acceleration system to timely process image data stored in the DDR storage unit in blocks; or, the data amount of the to-be-processed data block is set according to a frame rate of laser data input from the outside to the DDR storage unit, so as to support the hardware acceleration system to timely process laser point cloud maps stored in the DDR storage unit in blocks.

16. The chip according to claim 15, wherein space capacity of the SRAM dedicated storage unit is configured as a sum of data amount in the to-be-processed data block read by the data reading unit each time and data amount of intermediate data preexisting in the data reading unit.
